(19) United States
(12) Patent Application Publication
(10) Pub. No.: US 2006/0268590 A1
(43) Pub. Date: Nov. 30, 2006

(54) Rectifier diode of electric generator

(76) Inventor: Charng-Geng Sheen, Luchu Hsiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/139,476

(22) Filed: May 31, 2005

(51) Int. Cl. H05K 7/20

(52) U.S. Cl. 363/141

(57) ABSTRACT

A rectifier diode of electric generator applies to electric generators with violent vibrations, especially to those used in heavy-duty vehicles. Good conductivity in the rectifier diode is ensured to enhance stable operations of the electric generators. The rectifier diode has a main body, a conducting fixing component, a flexible conducting wire, and a connecting component. The main body has a cup with a semiconductor device therein and a lead electrically connected to the semiconductor device. The lead protrudes outwards. The conducting fixing component is connected to the lead. The flexible conducting wire is connected to the fixing component. The connecting component is connected to the distal end of the flexible conducting wire.

### BACKGROUND OF THE INVENTION

1. Field of the Invention

The present invention relates to a rectifier diode of electric generator and, more particularly, to a rectifier diode disposed in an automobile electric generator to rectify an AC power to a DC power and especially applicable to vehicles with violent vibrations such as heavy-duty vehicles.

2. Description of Related Art

A rectifier diode or an embedded type package of power semiconductor device indicates a diode rectifier embedded in a car or used in the industry. The rectifier diode is usually disposed in an electric generator to convert an AC power to a DC power. Because the rectifier diode is located on a high-temperature electric generator, its internal structure needs to have a high stability. Besides, because the rectifier diode is tightly embedded in a rectifier, it needs to endure a very large pressure when embedded into the rectifier.

The applicant of the present invention has proposed a related disclosure of U.S. Pat. No. 6,455,929B1 titled “embedded type package of power semiconductor device” published in Sep. 24, 2002, wherein an embedded type package of power semiconductor device is provided. This embedded type package of power semiconductor device won't crack when embedded, hence preventing the semiconductor chip from being incorrectly assembled into a cup. Moreover, a good heatsink structure is accomplished.

Although the above disclosure really has a good effect, it is found that crack of the lead of the rectifier diode may arise when it is assembled in a vehicle with violent vibrations such as a heavy-duty vehicle, hence causing bad electric connection in an electric generator.

As shown in FIG. 1, a prior art rectifier diode 20a is embedded into a heatsink shell 10a of a rectifier. The rectifier diode 20a has a metallic rod-shaped lead 22a electrically connected to a semiconductor device therein. The rectifier has an insulating board 30a with a plurality of connecting terminals 40a. Each connecting terminal 40a has a conducting bolt 42a protruding upwards, a connecting spacer 44a disposed on the top face of the insulating board 30a, a connecting portion 46a extending outwards from the connecting spacer 44a, and a clamping portion 48a formed at the distal end of the connecting portion 46a. The clamping portion 48a clamps the lead 22a and is electrically connected to the outside via the conducting blot 42a.

Although the above rectifier diode has a firm assembly, the vibrating force may be transmitted into the rectifier diode 20a via the rigid lead 22a when used in a vehicle with violent vibrations, hence causing bad electric connection of internal devices or even crack of the lead 22a.

### SUMMARY OF THE INVENTION

An object of the present invention is to provide a rectifier diode of electric generator applicable to electric generators with violent vibrations. Crack of the lead can be avoided to ensure good electric connection in the rectifier diode and also enhance the stability of operation of an electric generator.

Another object of the present invention is to provide a rectifier diode of electric generator, whose external conducting portion has flexibility to bear violent vibrations.

Yet another object of the present invention is to provide a rectifier diode of electric generator to improve its external conducting portion for simplifying the connection procedures with the outside.

To achieve the above objects, the present invention provides a rectifier diode of electric generator applicable to electric generators with violent vibrations. The rectifier diode of electric generator comprises a main body, a conducting fixing component, a flexible conducting wire, and a connection component. The main body has a cup and a lead. A semiconductor device is disposed in the cup. The lead is electrically connected to the semiconductor device and protrudes outwards. The conducting fixing component is connected to the lead. The flexible conducting wire is connected to the fixing component. The connecting component is connected to a distal end of the flexible conducting wire.

Because the flexible conducting wire matches the fixing component and the connecting component, violent vibrations can be endured to ensure good electric connection in the rectifier diode and also enhance the stability of operation of an electric generator. Moreover, the design of the connecting component can simplify the connection procedures with the outside.

### BRIEF DESCRIPTION OF THE DRAWINGS:

The various objects and advantages of the present invention will be more readily understood from the following detailed description when read in conjunction with the appended drawing, in which:

FIG. 1 is a local top view of a prior art rectifier diode assembled in a rectifier;

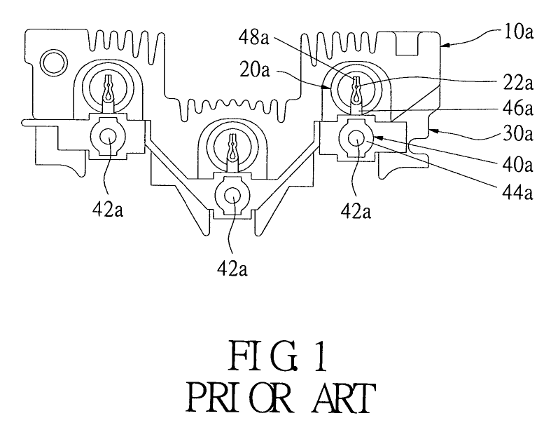

FIG. 2 shows an exploded side view and an assembly top view of a rectifier diode of electric generator of the present invention;

FIG. 3 is an assembly top view of a rectifier diode of electric generator of the present invention;

FIG. 3A is an assembly top view of a rectifier diode of electric generator according to a second embodiment of the present invention;

FIG. 4 is an assembly side view of a rectifier diode of electric generator of the present invention;

FIG. 4 A is a locally enlarged view of part A in FIG. 4; and

FIG. 5 is a perspective view of a rectifier diode of electric generator of the present invention when assembled into a heatsink structure of electric generator.

### DETAILED DESCRIPTION OF THE PREFERRED EMBODIMENTS

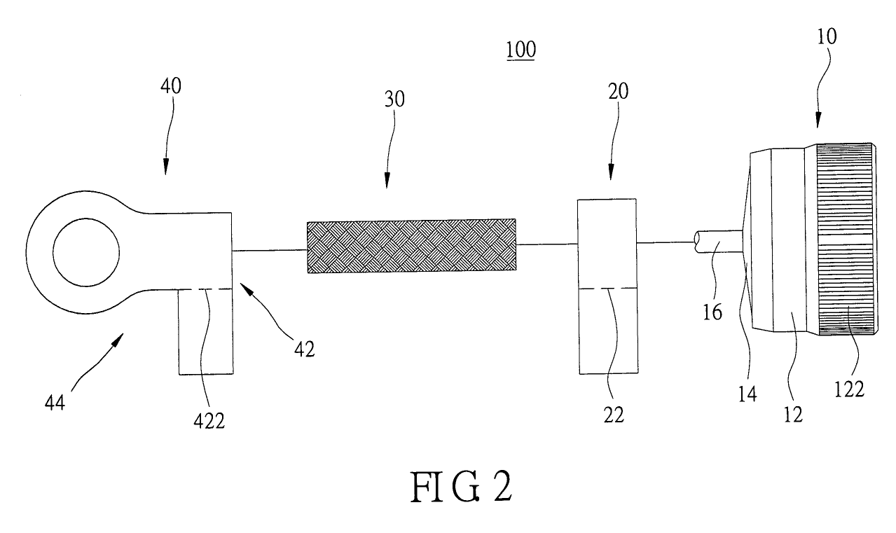

As shown in FIG. 2, the present invention proposes a rectifier diode of electric generator 100 applicable to electric generators with violent vibrations. The rectifier diode 100 comprises a main body 10, a fixing component 20, a flexible conducting wire 30, and a connecting component 40.

The main body 10 has a cup 12 and a lead 16. A semiconductor device (not shown) is disposed in the cup 12. The lead 16 is electrically connected to the semiconductor device and protrudes outwards. A plurality of grooves 122 is provided around the cup 12 to enhance the fixing force of embedding. The lead 16 and the semiconductor device are fixed in the cup 12 by insulating gel 14. The fixing component 12 is made of material of good conductivity, and is connected to the lead 16. The flexible conducting wire 30 is connected to the fixing component 20. The connecting component 40 is connected to the distal end of the flexible conducting wire 30 for connection with an external device.

The fixing component 20 is made of a metal sheet, and is folded along a fold line 22 to clamp the lead 16 and the flexible conducting wire 30. In a preferred embodiment of the present invention, the fixing component 20 is made of copper material and plated with nickel alloy. The copper material has a good conductivity. Because the rectifier diode 100 is usually used in a high-temperature environment, the fixing component 20 of copper material is electroplated with nickel alloy to avoid oxidation.

In this preferred embodiment of the present invention, the connecting component 40 is also made of a metal sheet, and has a fixing portion 42 and an extended portion 44 extending outwards from the fixing component 42. The fixing portion 42 is a rectangular sheet, and is folded along a fold line 422 to clamp the distal end of the flexible conducting wire 30. The connecting component 40 is preferably to be made of copper material and electroplated with nickel alloy and avoid oxidation.

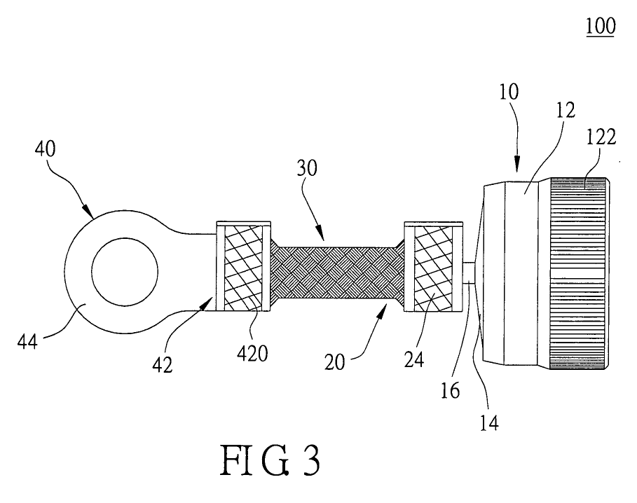

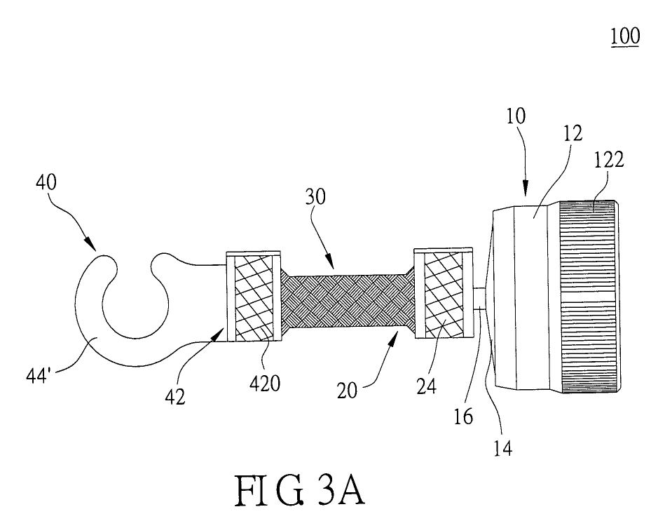

As shown in FIG. 3, in order to ensure that the fixing component 20 can firmly connect the lead 16 and the flexible conducting wire 30, the fixing component 20 is preferably to be welded to the lead 16 and the flexible conducting wire 30. Welding means the metal of the fixing component 20 is melt and connected with the lead 16 and the flexible conducting wire 30 to achieve a firm connection. A preferred method of welding it to form a beveled shape at a welded position 24 of the fixing component 20. That is, the fixing component 20 shrinks gradually from the lead 16 to the flexible conducting wire 30. The welded position 24 of the fixing component 20 forms a beveled shape to have a better welding result. Of course, the welded position 24 of the fixing component 20 can also be of a planar shape.

The flexible conducting wire 30 is preferably to be a copper braid lead formed by braiding several thin wires. For example, the number of thin copper wires of the flexible conducting wire 30 can reach about 800. A copper braid lead has a good conductivity. A braid lead with several thin wires has a better flexibility and won't crack easily. The flexible conducting wire 30 is further electroplated with nickel alloy to avoid oxidation.

The extended portion 44 of the connecting component 40 is a screwable metal sheet. Speaking more specifically, the extended portion 44 is a ring-shaped metal sheet. The extended portion 44 can thus be conveniently screwed to a conducting bolt with a nut.

As shown in FIG. 3A, the extended portion 44 of the connecting component 40 can also be a hook-shaped metal sheet.

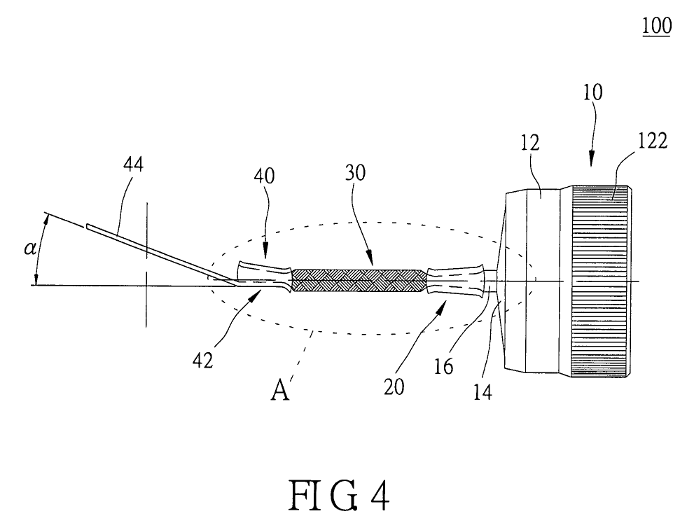

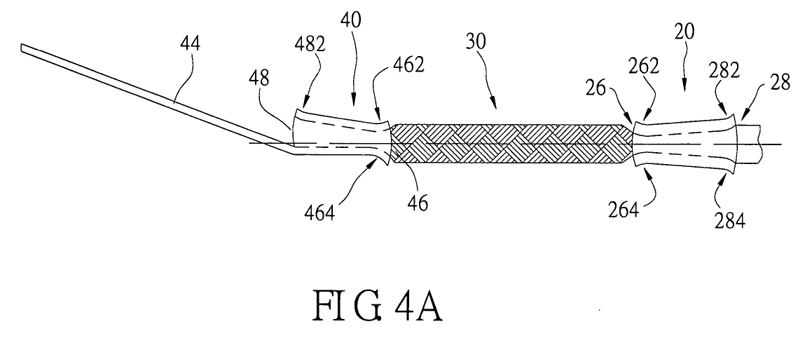

As shown in FIGS. 4 and 4A, when the rectifier diode 100 of the present invention is connected, the edge of the fixing component 20 is processed to prevent the sharp edge from damaging the wire due to frequent vibrations. In this preferred embodiment, the fixing component 20 not only has a beveled welded position; it is also connected to one end of the lead 16 to form an outward opening 28. The opening 28 is bent to be of an arc shape, i.e., the opening 28 forms an upper bevel edge 282 and a lower bevel edge 284. The smooth upper bevel edge 282 and lower bevel edge 284 are used to achieve a protection effect. Besides, the fixing component 20 is connected to one end of the flexible conducting wire 30 to also form an outward opening 26. The opening 26 is bent to be of an arc shape, i.e., the opening 26 forms an upper bevel edge 262 and a lower bevel edge 264.

The fixing portion 42 of the connecting component 40 is preferably to be welded to the flexible conducting wire 30. A welded position 420 (shown in FIG. 3) of the fixing portion 42 is also preferred to be of a beveled shape to have a better welding effect. Of course, the welded position 420 can also be of a planar shape. On the other hand, for easy assembly, the extended portion 44 is fixed to a conducting bolt by means of screwing, and an obtuse included angle exists between the fixing portion 42 and the extended portion 44 of the connecting component 40. The included angle α between the extended portion and the horizontal line is about

20 degrees.

In order to protect the flexible conducting wire 30, the fixing portion 42 of the connecting component 40 is connected to one end of the flexible conducting wire 30 to form an outward opening 46. The opening 46 is bent to be of an arc shape, i.e., the opening 46 forms an upper bevel edge 462 and a lower bevel edge 464.

The other end of the connecting component 40 is an open end 48. An upper bevel edge 482 is also formed above the open end 48.

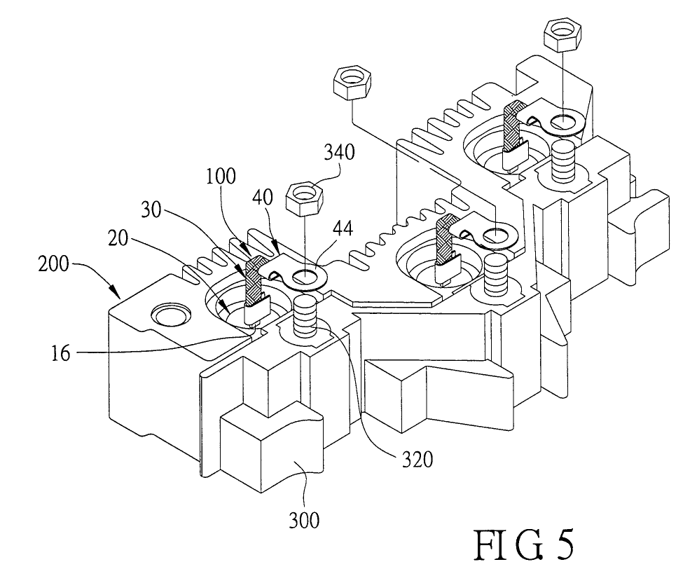

As shown in FIG. 5, the main body 10 of the rectifier diode 100 of the present invention is fixed in a heatsink shell 200 by means of embedding. The flexible conducting wire 30 is bent toward an insulating board 300. The insulating board 300 has a plurality of conducting bolts 320. Because the extended portion 44 of the connecting component 40 is a screwable metal sheet, the extended portion 44 can be easily screwed to one of the conducting bolts 320 with a nut 340. Therefore, the assembly procedures of the rectifier diode 100 can also be simplified without the need of clamping or welding in the prior art.

The present invention has the following features and functions.
1. Because the flexible conducting wire 30 has flexibility and can be firmly connected to the main body 10, it is applicable to electric generators with violent vibrations to prevent the vibration force from transmission to the rectifier diode 100, hence ensuring good electric connection in the rectifier diode and also enhancing the stability of operation of an electric generator.
2. The flexible conducting wire 30 can improve the structure of the external conducting portion of the rectifier diode 100 to endure violent vibrations and also simplify the connection procedures with the outside.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A rectifier diode of electric generator applicable to electric generators with violent vibrations, comprising:
a main body having a cup and a lead, a semiconductor device being disposed in said cup, said lead being electrically connected to said semiconductor device and protruding outwards;
a conducting fixing component connected to said lead;
a flexible conducting wire connected to said fixing component; and
a connecting component connected to a distal end of said flexible conducting wire.

2. The rectifier diode of electric generator as claimed in claim 1, wherein a plurality of grooves are formed on a periphery of said cup.

3. The rectifier diode of electric generator as claimed in claim 1, wherein said fixing component is made of a metal sheet, and is folded to clamps said lead and said flexible conducting wire.

4. The rectifier diode of electric generator as claimed in claim 3, wherein said fixing component is made of copper material and is electroplated with nickel alloy.

5. The rectifier diode of electric generator as claimed in claim 1, wherein said fixing component is welded to said lead and said flexible conducting wire.

6. The rectifier diode of electric generator as claimed in claim 5, wherein said fixing component has a beveled welded position.

7. The rectifier diode of electric generator as claimed in claim 5, wherein said fixing component has a planar welded position.

8. The rectifier diode of electric generator as claimed in claim 1, wherein the end of said fixing component connected to said lead forms an outward opening, and said opening is bent to be of an arc shape.

9. The rectifier diode of electric generator as claimed in claim 1, wherein the end of said fixing component connected to said flexible conducting wire forms an outward opening, and said opening is bent to be of an arc shape.

10. The rectifier diode of electric generator as claimed in claim 1, wherein said flexible conducting wire is a copper braid lead.

11. The rectifier diode of electric generator as claimed in claim 10, wherein said flexible conducting wire is further electroplated with nickel alloy.

12. The rectifier diode of electric generator as claimed in claim 1, wherein said connecting component is made of a metal sheet, and has a fixing portion and an extended portion extending outwards from said fixing portion.

13. The rectifier diode of electric generator as claimed in claim 12, wherein said connecting component is made of copper material and electroplated with nickel alloy.

14. The rectifier diode of electric generator as claimed in claim 12, wherein an included angle exists between said fixing portion and said extended portion of said connecting component.

15. The rectifier diode of electric generator as claimed in claim 12, wherein said fixing portion of said connecting component is a rectangular sheet, and is bent to clamp a distal end of said flexible conducting wire.

16. The rectifier diode of electric generator as claimed in claim 15, wherein said fixing portion of said connecting component is welded to said flexible conducting wire.

17. The rectifier diode of electric generator as claimed in claim 16, wherein said fixing portion has a beveled welded position.

18. The rectifier diode of electric generator as claimed in claim 16, wherein said fixing portion has a planar welded position.

19. The rectifier diode of electric generator as claimed in claim 16, wherein the end of said fixing portion of said connecting component connected to said flexible conducting wire forms an outward opening, and said opening is bent to be of an arc shape.

20. The rectifier diode of electric generator as claimed in claim 12, wherein said extended portion of said connecting component is a screwable metal sheet.

21. The rectifier diode of electric generator as claimed in claim 20, wherein said extended portion of said connecting component is a ring-shaped metal sheet.

22. The rectifier diode of electric generator as claimed in claim 20, wherein said extended portion of said connecting component is a hook-shaped metal sheet.
